(19) United States
(12) Patent Application Publication
(10) Pub. No.: US 2017/0278695 A1
(43) Pub. Date: Sep. 28, 2017

(54) POLYMER REMOVAL USING CHROMOPHORES AND LIGHT EXPOSURE

(71) Applicant: Tokyo Electron Limited, Minato-ku (JP)

(72) Inventor: Ian J. BROWN, Portland, OR (US)

(73) Assignee: Tokyo Electron Limited, Minato-ku (JP)

(21) Appl. No.: 15/468,995

(22) Filed: Mar. 24, 2017

Related U.S. Application Data
(60) Provisional application No. 62/313,351, filed on Mar. 25, 2016.

(51) Int. Cl. H01L 21/02; B08B 7/00; H01L 21/324; H01L 21/311; H01L 21/3105; H01L 21/3115

(52) U.S. Cl. CPC H01L 21/0206; H01L 21/31058; H01L 21/3115; H01L 21/324; H01L 21/31138; B08B 7/0057

(57) ABSTRACT

A method for processing a substrate includes receiving a substrate having fluorinated polymer residue on a surface of the substrate. The fluorinated polymer residue is treated to provide a treated fluorinated polymer residue having increased sensitivity to electromagnetic (EM) radiation exposure. The treated fluorinated polymer residue is treated to EM radiation in an oxygen-containing environment to facilitate a cleaning process for removing the fluorinated polymer residue from the substrate.

### CROSS-REFERENCE TO RELATED APPLICATIONS

This patent Application claims the benefit of Provisional Application Ser. No. 62/313,351 filed on Mar. 25, 2016. The entire content of this provisional application is incorporated herein by reference.

### BACKGROUND OF THE INVENTION

This disclosure relates to processing of semiconductor materials, and, in particular, to cleaning techniques and material removal techniques.

Fabrication of integrated circuits and semiconductor devices can involve many different types of processing techniques. Such techniques generally involve patterning a substrate and using the pattern to make various sacrificial and/or permanent structures. For example, photolithography can be used to create patterned layers using a thin layer of radiation-sensitive material, such as photoresist. This radiation-sensitive layer is transformed into a patterned mask that can be used to etch or transfer a pattern into one or more underlying layers on a substrate. Thus, the patterned layer of photoresist can act as a mask for directional (anisotropic) etching of one or more underlying layers. Any of various materials can be patterned, including oxides, organic materials, hardmasks, metals, etc.

Fabrication of integrated circuits and semiconductor devices can be a cyclical process of depositing materials, modifying materials, patterning materials, and removing materials. It is common to have a need to remove one type of material without removing other types of materials on a given substrate. Various cleaning processes can be implemented to selectively remove or clean materials off of a given substrate. Such cleaning processes can include both wet cleaning techniques (such as reactive liquid chemicals) and dry cleaning techniques (such as plasma-based cleaning) using particular chemistries and/or physical mechanisms to clean or remove materials from a substrate. Generally, it is important to selectively remove a material without damaging remaining underlying materials.

### SUMMARY OF THE INVENTION

As noted in the Background, it is important to selectively remove a material without damaging remaining underlying materials. This need to avoid damage to underlying materials can become more critical as device nodes are reduced to smaller sizes. Materials that are selectively removed during semiconductor processing can include carbon films, photoresists, and post-etch polymers. Conventionally, such films can be removed using a high temperature oxidation process, or plasma ashing process. Such high-temperature and plasma-based removal techniques, however, can damage underlying layers. For example, low-k dielectrics and other insulating materials can be easily damaged by conventional removal techniques such as plasma-based removal and aggressive wet cleaning.

Post-etch polymer residue can be especially difficult to remove. Etching processes for etching silicon, silicon oxides and carbon-doped oxides rely on use of mixtures of perfluorohydrocarbon and hydrocarbon gases in a reactive ion etch chamber. A consequence of such etching processes is fluorinated polymer residue on the substrate, which should be removed. Irradiation of these post-etch polymers with ultraviolet (UV) light at wavelengths above 185 nm can enable easier removal of these films in a subsequent wet clean process. Such UV irradiation, however, can damage underlying films. For example, the present inventors recognized that while increasing a UV dose can be helpful for removal of polymer residue, such increased UV exposure can damage materials and devices on the substrate.

Accordingly, an object of the present invention is to facilitate removal of post-etch polymer residue by exposing the residue to electromagnetic (EM) radiation while minimizing damage effects of such radiation to materials underlying the polymer residue.

One embodiment includes a method for processing a substrate. The method includes receiving a substrate having fluorinated polymer residue deposited on a surface of the substrate. The polymer residue is treated to increase sensitivity of the polymer residue to EM radiation. The treated post-etch polymer residue is exposed to EM radiation in an oxygen-containing environment to facilitate removal of the post-etch polymer.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

FIG. 1 is a flow chart showing a method for processing a substrate according to one embodiment;

FIGS. 2A, 2B, 2C, 2D, 2E, 2F, 2G and 2H illustrate absorption spectrums for various chromophores or dyes;

FIGS. 3A, 3B, 3C, and 3D show a comparison of absorption spectrums for various chromophores or dyes on the same graphical scale;

FIGS. 4A and 4B are tables illustrating example compounds and atomic structures with corresponding light wavelengths for generating singlet oxygen for use with techniques disclosed herein;

FIG. 5 is a flow chart illustrating an example process flow for performing liquid phase chromophore doping of polymer film on a system such as a substrate cleaning tool for semiconductor wafers;

FIG. 6 illustrates an example of process flow for performing vapor phase chromophore doping of polymer film prior to light irradiation (visible and/or UV) and wet clean; and

FIGS. 7A, 7B and 7C show example embodiments of substrate processing tools.

### DETAILED DESCRIPTION

As noted above, one object of the present invention is to facilitate removal of post-etch polymer residue by exposing the residue to electromagnetic (EM) radiation while minimizing damage effects of such radiation to materials underlying the polymer residue.

Irradiation of fluorinated post-etch polymer films with ultraviolet light in an oxygen-containing environment modifies the chemical composition of the polymer fragments in the film. Increasing a UV dose can result in increasing amounts of alpha fluoro substituted carbonyls (FₓC═O) and alcohol function groups (C—OH) being formed within the polymer network. In contrast, however, increasing the UV dose can decrease amounts of saturated CF₂. The oxygen-containing environment can be a liquid containing oxygen and/or a process gas containing oxygen.

One mechanism for these changes in the post-etch polymer film is an indirect photodegradation because some of the UV wavelengths used (>230 nm) are not sufficient to directly scission the strong C—F bonds (480-540 kJ/mol) in the polymer residue. Photodegradation mechanisms, as disclosed herein, includes absorption of incident UV light (e.g. >230 nm) via carbonyl chromophores and conjugated carbon chains within the polymer fragments, as well as energy transfer with oxygen to form singlet oxygen (¹O₂) from the triplet oxygen (³O₂) present in the substrate processing chamber. Singlet oxygen is highly oxidizing compared to the common state of oxygen in its triplet state. Singlet oxygen has sufficient reactivity to chemically modify the fluorinated post-etch polymer by incorporating oxygen to form carbonyls (C═O) and alcohols (C—OH), and to cause chain scission of the polymer fragment and oxidation to CO or CO₂ vapor.

Techniques herein include widening the process window of the EM exposure step by increasing EM sensitivity of the post etch polymer film. By increasing the EM sensitivity, the overall EM exposure dose can be reduced which can limit any negative impact of the EM radiation on the underlying materials (e.g. low-k dielectric). For example, techniques disclosed herein include methods and systems for increasing the sensitivity of a post-etch polymer film to light in the UV and visible spectrum light wavelengths to generate singlet oxygen. Generation of singlet oxygen can help remove CF₂ bonds from the post-etch polymer and facilitate complete removal with wet clean chemistry.

The present inventors recognized that post etch polymer films typically exhibit low levels of carbonyls that have a broad absorption range from 240 nm to 300 nm with a polymer film thicknesses of up to 10-20 nm. Thus, plasma-deposited polymer has relatively low absorption of UV radiation and can allow UV to penetrate into the underlying film. Depending on a composition of the underlying film, the underlying film can be damaged by the UV light transmitted through the polymer film.

With techniques disclosed herein, sensitivity of the polymer film is increased by depositing a targeted chromophore on the substrate having the post-etch polymer thereon. This chromophore enables significantly improved photon absorption generally, UV absorption, and/or absorption at longer light wavelengths (including visible light) which have less energy to damage the underlying sensitive film. Higher photon absorption will support higher rates of singlet oxygen generation at the polymer surface for easier removal of the polymer. This can provide for lower UV-Visible dose to be applied, and for shortening the overall process time.

To maximize a photon yield, singlet oxygen generated by the chromophores benefits by reacting with the fluorinated post-etch polymer before diffusing from the substrate into the process chamber atmosphere or diffusing through the polymer film to an underlying material/layer. If the underlying material is porous (e.g. a porous low-k dielectric with composition of Si, C, O and H or spin-on type porous/merosporousmaterials) then it is advantageous to react photons with the chromophores before reaching the underlying layer where damage can result.

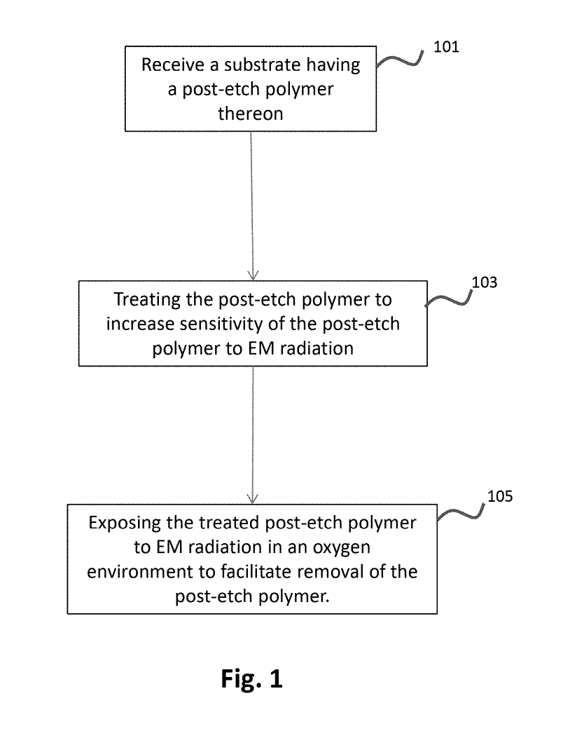

FIG. 1 is a flow chart showing a method for processing a substrate according to one embodiment. Step 101 includes receiving a substrate having fluorinated polymer residue deposited on a working surface of the substrate. The fluorinated polymer residue is typically deposited as a result of a plasma etch transfer of a given relief pattern into one or more underlying layers. A corresponding plasma used for the etch transfer includes fluorine-containing and hydrocarbon-containing gasses. In other words, a wafer is received or otherwise accessed after a plasma-based etch that leaves polymer byproduct on the wafer. The one or more underlying layers can be silicon, silicon oxide, carbon-doped oxide, low-k material, and/or hardmask material. The substrate can have micro-fabricated structures thereon such as transistors, trenches, vias, etc.

In step 103, the post-etch polymer is treated to increase sensitivity of the polymer material to EM exposure. In one embodiment, sensitivity is increased by adding an absorption-enhancing material to the substrate. The absorption-enhancing material can be deposited on the substrate and polymer residue, or incorporated within the polymer residue. The absorption enhancing material can include a chromophore that has a light-absorption capacity which is greater than a light-absorption capacity of the fluorinated polymer residue itself. For example, the chromophore has a greater capability of generating singlet oxygen as compared to the fluorinated polymer residue.

The absorption-enhancing material can include a monomer species, an oligomer species, or a polymer species containing carbonyl groups that increase absorption of electromagnetic (EM) radiation that causes generation of singlet oxygen. Such absorption-enhancing material can be deposited via vapor phase deposition, initiated chemical vapor deposition (iCVD), or via spin-on deposition of a liquid comprising a solvent and solute. Vapor phase deposition can include exposing the substrate to peroxygen species. Liquid deposition can include depositing a species selected from the group consisting of monomer, oligomer, and polymer. Optionally, a fluorine-scavenging species can be deposited with the chromophore.

In other embodiments, the absorption-enhancing material includes two (or more) dyes. Specific dyes and or light sources can be selected to be matched. For example, two light sources can be matched to the two dyes such that the two light sources respectively provide light wavelengths at peak absorption values of the two dyes for generating singlet oxygen. Depositing the absorption-enhancing material on the substrate increases a sensitivity of the fluorinated polymer residue to ultraviolet light or visible light with respect to breaking chemical bonds within the fluorinated polymer.

Next, in step 105, the fluorinated polymer residue and the absorption-enhancing material is irradiated with light in an oxygen-containing environment as shown by step 105. Irradiating with light includes irradiating with ultraviolet light and/or visible spectrum light. The ultraviolet light includes wavelengths that generate singlet oxygen from the absorption-enhancing material. The visible spectrum light also includes wavelengths that generate singlet oxygen from the absorption-enhancing material.

Exposing in step 105 can be followed by a wet clean process that uses liquid chemistry to remove the fluorinated polymer residue from the substrate. For example, liquid chemistry can be deposited on a spinning substrate that removed the modified polymer film.

One embodiment herein for improving yield of singlet oxygen is to heat a substrate while illuminating the chromophore with a wavelength of light for generating singlet oxygen. A given substrate can be heated by using a heated chuck, steam, and/or by infrared radiation or a chromophore illumination light source or other means. For example, a broadband flash lamp can emit from 190 nm up to 1100 nm wavelength light and can heat a substrate of silicon up to 400° C. Other embodiments include generating singlet oxygen from chromophores and visible light at significantly lower temperatures such as lower than 200° C., 100° C., and even at room temperature.

For sensitive film stacks, keeping a substrate temperature below 400° C. or 200° C. or lower is beneficial. Thus, selection of a given substrate temperature to maintain during irradiation can depend on underlying substrate materials. In general, higher substrate temperatures typically permit shorter irradiation duration during pretreatment, but higher temperatures can damage materials on some substrates. For robust substrate materials higher temperatures can be used, but for less robust materials lower temperatures are more beneficial. For example, thermally-cured films (deposited and then baked) that have not been exposed to UV radiation can benefit by using visible light with deposited chromophores to assist with removal of fluorinated post-etch residue on dielectrics and films. Thus, the combination of particular thermal and EM exposure amounts of the treated polymer residue may be selected based on the nature of the materials underlying the post-etch polymer film.

Using visible light and chromophores (or combinations thereof) can be beneficial regardless of a process temperature. For example, some dielectric materials are UV cured or hardened. Other dielectric materials, however, are not UV cured and thus can be sensitive to UV/Air exposure in that such dielectric materials can be damaged by UV light. Accordingly, modifying the post-etch polymer with chromophores and visible light is beneficial for some material combinations.

Techniques for increasing the EM radiation sensitivity of the polymer film include actively adding monomers, oligomers or polymer species containing carbonyl groups and/or conjugated carbon bonds onto a post etch substrate to increase absorption of electromagnetic radiation and generation of singlet oxygen. By having a higher concentration of carbonyl chromophores, UV absorption and generation of singlet oxygen is increased. Also, having a higher generation of singlet oxygen accelerates further oxygen incorporation into the plasma-deposited fluoropolymer film which facilitates removal of the film, for example, by wet etch.

There are many options for adding carbonyl species to the post etched polymer surface. For example, an oxygen-containing species may be added to the plasma after patterning to encourage more C═O species being formed. Such plasma processing can be challenging because of a risk of damaging low-k dielectric materials with high energy oxygen species. Another option is vapor phase deposition in a post-etch treatment chamber to expose the substrate to carbonyl monomer, oligomer or polymer vapor. Vapor can be below, at, or above saturation conditions within a corresponding chamber. Deposition rate and amount of carbonyl species onto the substrate can be controlled by controlling temperature of the substrate relative to given vapor saturation conditions (i.e. temperature of vapor vs substrate).

Yet another option is using initiated chemical vapor deposition (iCVD). An iCVD process can deposit polymers onto a patterned substrate. One advantage of iCVD is an ability to perform a conformal deposition or non-conformal deposition of thin polymer/oligomer films, and also the ability to polymerize monomers in-situ. Deposition of oligomers and polymers are preferable for back-end-of-line (BEOL) post etch processes to prevent penetration of monomers into porous low-k dielectrics. Another option is spin depositing a liquid containing a solvent and solute, which can be a carbonyl-containing monomer, oligomer or polymer. Additionally, exposure to peroxygen vapor such as ozone, atomic oxygen, singlet oxygen, hydrogen peroxide or hydroxyl radical can also be performed.

Techniques herein can be enhanced by adding fluorine-scavenging functionality into a deposited chromophore. Free fluorine from the etch process contributes to queue time effects that can have a significant negative yield impact on an integrated device. Fluorine scavenging materials are conventionally available, such as STF products from Stabilization Technologies, LLC or common silicon containing fluorine scavengers such as tetraethyl orthosilicate (TEOS), diethylsilane, tetrafluorosilane, benzene or acetylene containing hydrocarbon, carbon monoxide vapor. For use of carbon monoxide, the atmosphere during chromophore deposition can be continuously purged with free carbon monoxide to aid in removal of free fluorine.

In some embodiments, an absorption enhancing material (such as a given chromophore or set of chromophores) to be deposited can be tuned to radiation that is selected to be used for radiation assisted pre-clean. For example, if a given light source selected for use (lamp, laser, etc.) provides broadband radiation from 230 nm up to 1100 nm, then one or more chromophores can be deposited on the polymer residue to absorb as many wavelengths as possible. By way of a non-limiting example, 523 nm green light (or white light containing such green light), can be used for a deposited chromophore (e.g. Rose Bengal) that reacts to visible spectrum light.

Another option is dispensing a chromophore rich liquid onto a spinning substrate while at the same time irradiating with light that causes a corresponding chromophore(s) to generate singlet oxygen. The chemistry can be continually dispensed to keep the substrate fully wetted, or the chemistry can be pulsed allowing the substrate surface to dry in between pulses.

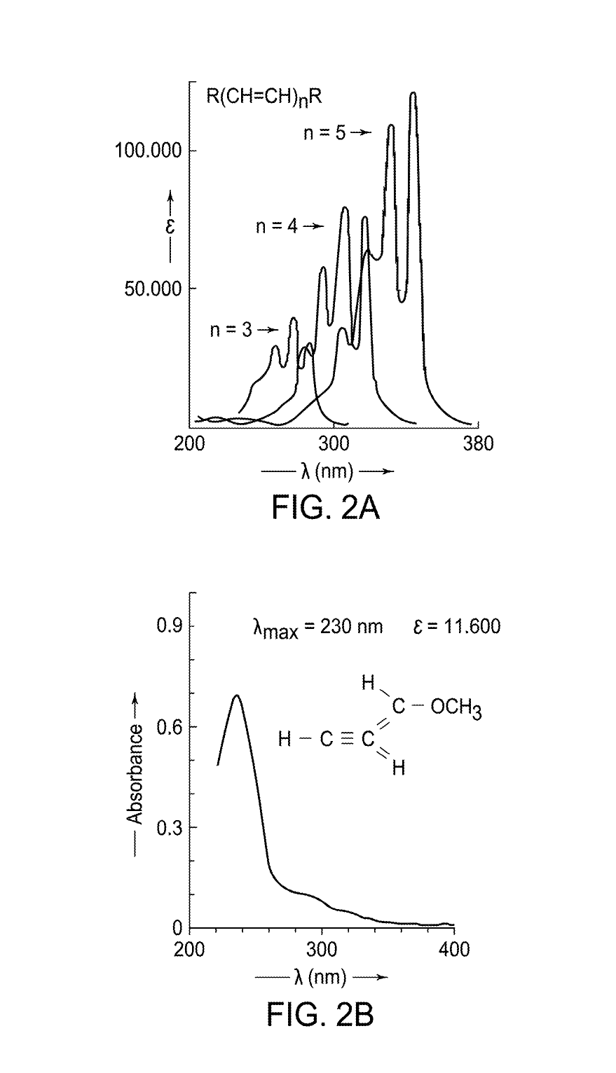

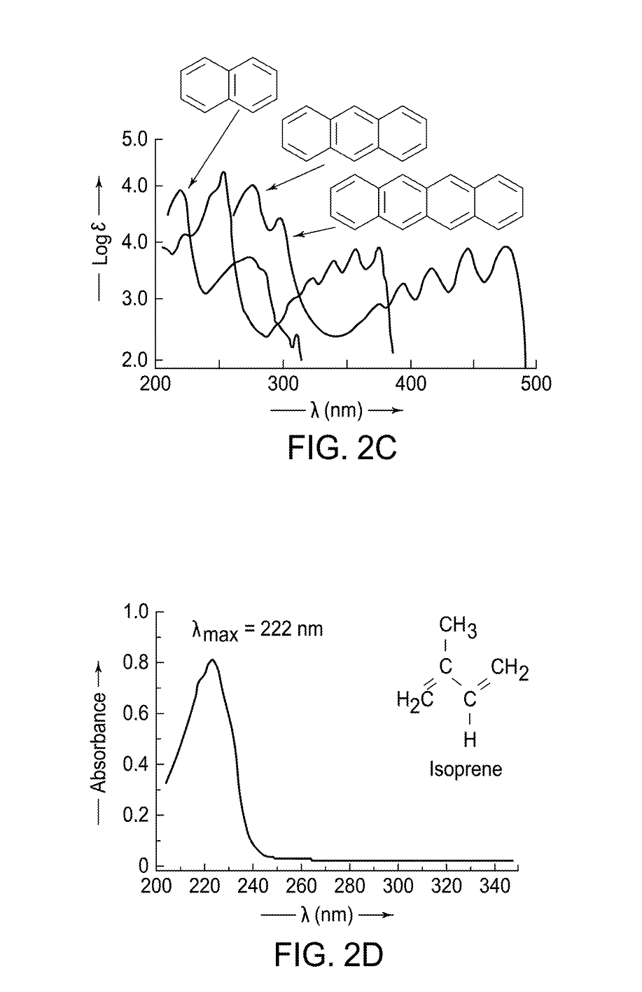

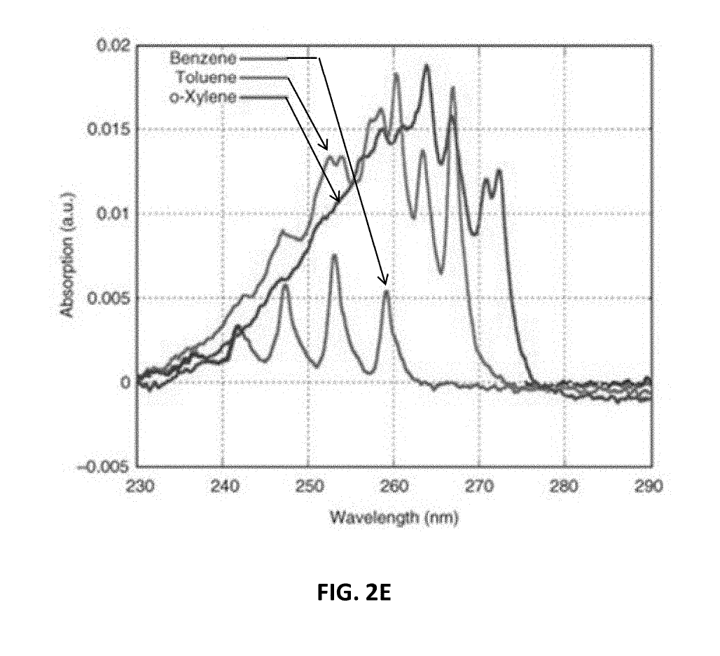

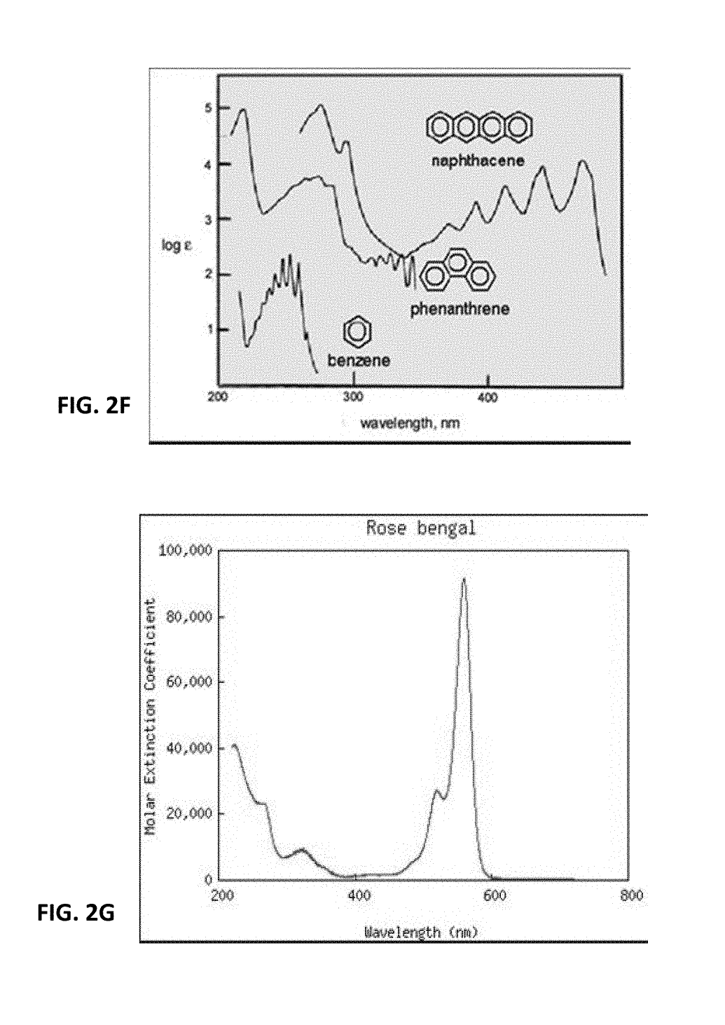

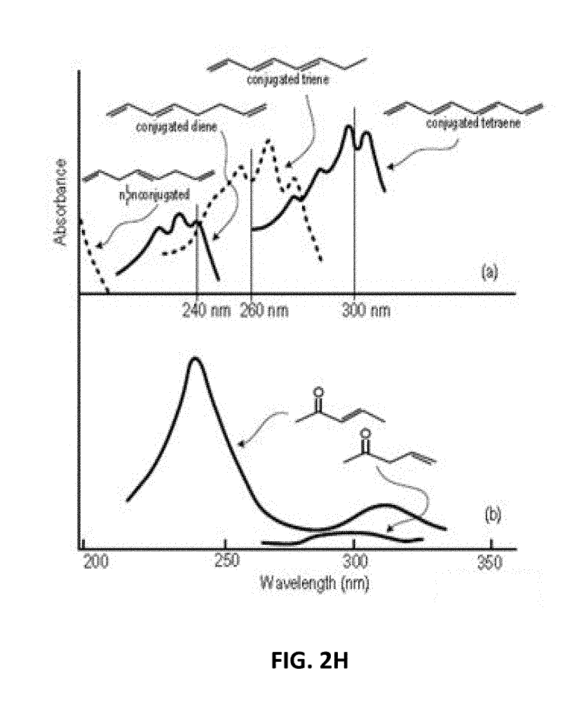

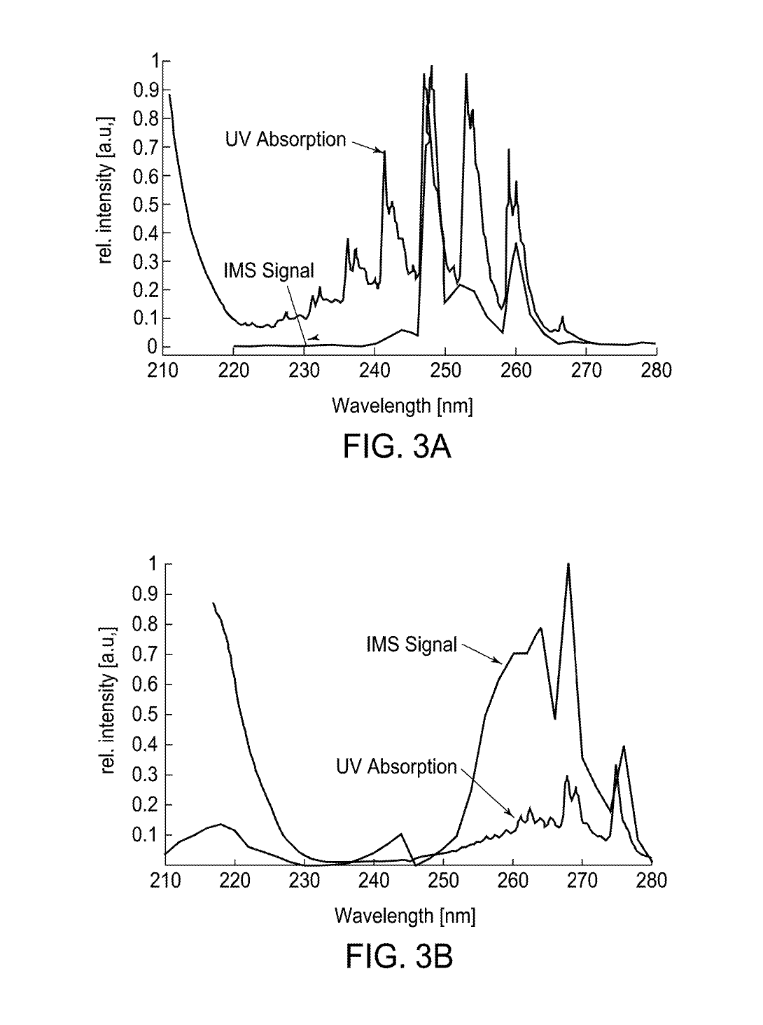

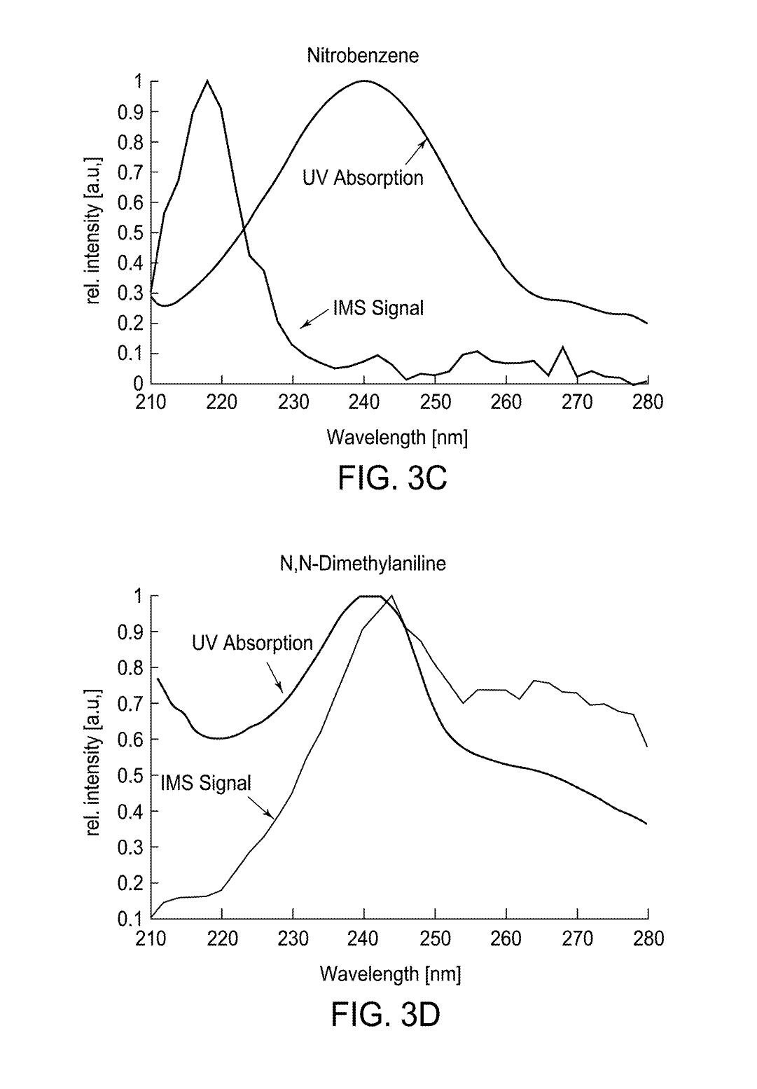

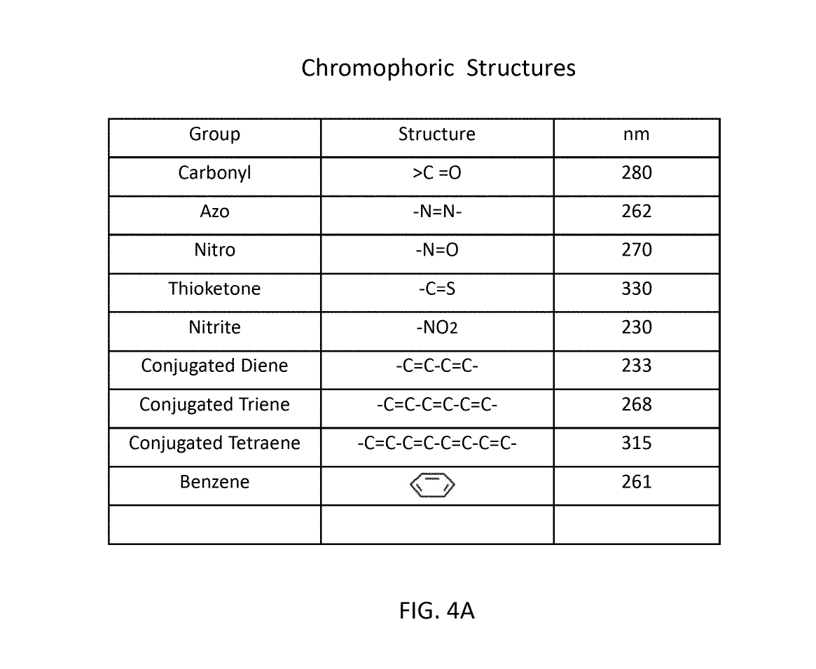

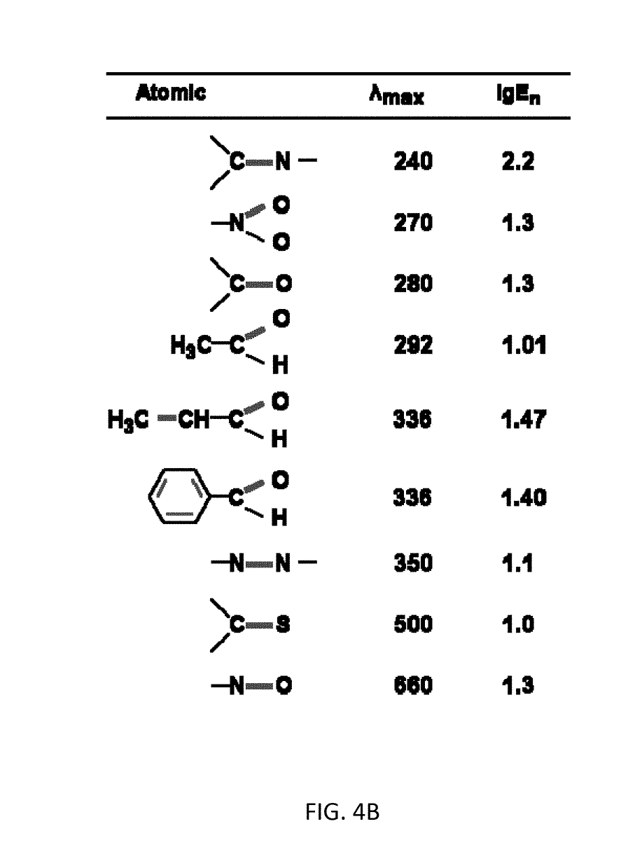

There are multiple selectable embodiments herein because of the absorption of various organic moieties to radiation. For example for increased absorption of 260 nm radiation, more conjugated dienes can be incorporated on and/or within the post etch polymer film. Generally, the larger the molecule the longer the wavelength of radiation that is absorbed. FIGS. 2A to 2H illustrate absorption spectrums for various chromophores or dyes. FIGS. 3A, 3B, 3C, and 3D show a comparison of absorption spectrums for various chromophores or dyes on the same graphical scale. In some embodiments, the absorption enhancing material is selected to have a peak absorption wavelength matching the light irradiation source in order to maximize generation of singlet oxygen. FIGS. 4A and 4B are tables illustrating example compounds and atomic structures with corresponding light wavelengths for generating singlet oxygen for use with techniques disclosed herein.

Absorption-enhancing materials herein can include dyes, organic photosensitizers, etc. Note that any number of dyes, photosensitizers, or combinations of dyes, can be used with embodiments herein. Example dyes for selection include, but are not limited to: angelicins, biological macromolecules, chalcogenapyrillium dyes, chlorins (misc.), chlorophylls, coumarins (misc.), cyanines, DNA and related compounds, drugs (misc.), flavins and related compounds, fullerenes, metallophthalocyanines, metalloporphyrins, methylene blue derivatives, naphthalim ides, naphthalocy anines, natural compounds (misc.), nile blue derivatives, NSAIDs (nonsteroidal anti-inflammatory drugs), perylenequinones, phenols, pheophorbides, pheophytins, photosensitizer dimers and conjugates, phthalocyanines, porphycenes, porphyrins, psoralens, purpurins, quinones, retinoids, rhodamines, thiophenes, verdins, vitamins, xanthene dyes.

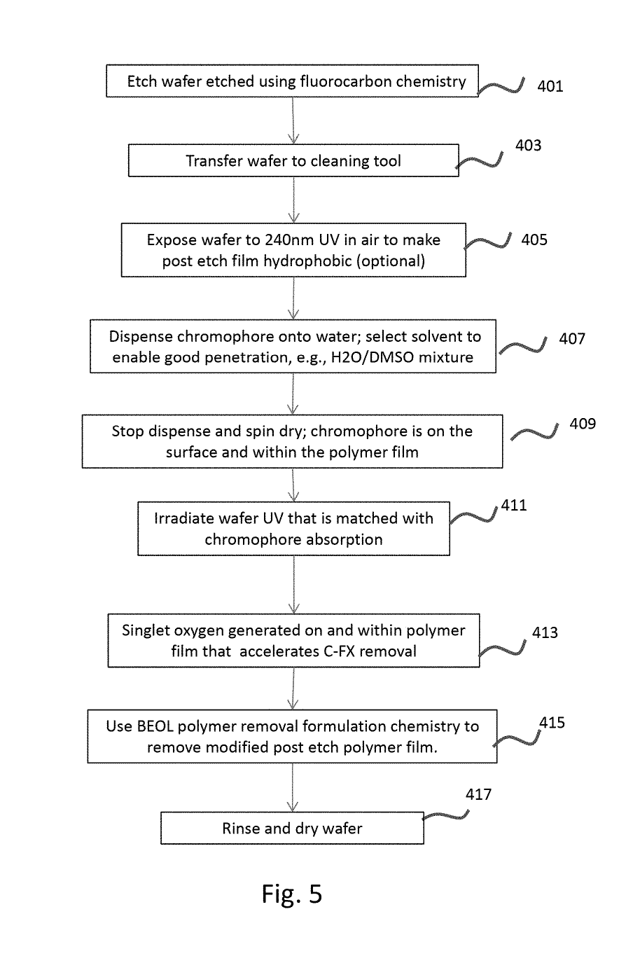

FIG. 5 is a flow chart illustrating an example process flow for performing liquid phase chromophore doping of polymer film on a system such as a substrate cleaning tool for semiconductor wafers. Note that some chromophores can have chemical structures that enable singlet oxygen generation from white light or various light wavelengths within the visible spectrum. Using such chromophores can make subsequent UV exposure not needed. In other words, after depositing one or more dyes on the substrate, sufficient singlet oxygen can be created from visible light that UV light exposure is not required to pretreat the fluorinated polymer for subsequent removal, which minimizes any potential for damage to underlying materials from UV exposure.

In step 401, the wafer etched using fluorocarbon chemistry, resulting in post-etch polymer film deposition as noted above. The substrate is then transferred to a cleaning tool in step 403, and exposed to UV wavelengths greater than 240 nm UV in air to make the post etch film hydrophobic (optional).

A chromophore is dispensed onto the substrate in step 407, with a solvent selected to enable good penetration (e.g. H₂O/DMSO mixture). Dispensing is stopped and the substrate is spin died in step 409, such that the chromophore is on the surface and within the polymer film.

In step 411 the substrate is irradiated with UV that is matched with an absorption peak wavelength of the chromophore. Exposure leads to generation of singlet oxygen on and within polymer film, which accelerates C—Fᵣ removal as shown in step 413. In 415, back end of line (BEOL) polymer removal formulation chemistry is used to remove modified post etch polymer film, and the substrate is rinsed and dried in 417

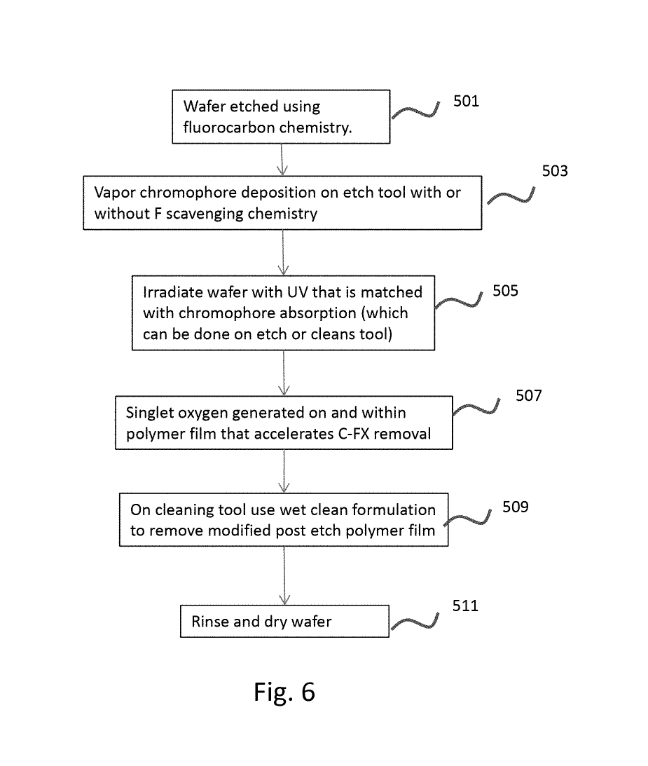

FIG. 6 illustrates an example of process flow for performing vapor phase chromophore doping of polymer film prior to light irradiation (visible and/or UV) and wet clean. In 501, the wafer is etched using fluorocarbon chemistry, and a vapor chromophore is deposited within the etch tool with or without F scavenging chemistry in step 503. In 505, the wafer is irradiated with UV that is matched with chromophore absorption (which can be done on etch or cleans tool). In 507, singlet oxygen is generated on and within polymer film that accelerates C-Fₓ removal. In 509, the wafer is transferred to a cleaning tool which uses wet clean formulation to remove modified post etch polymer film. The wafer is rinsed and dried in 511.

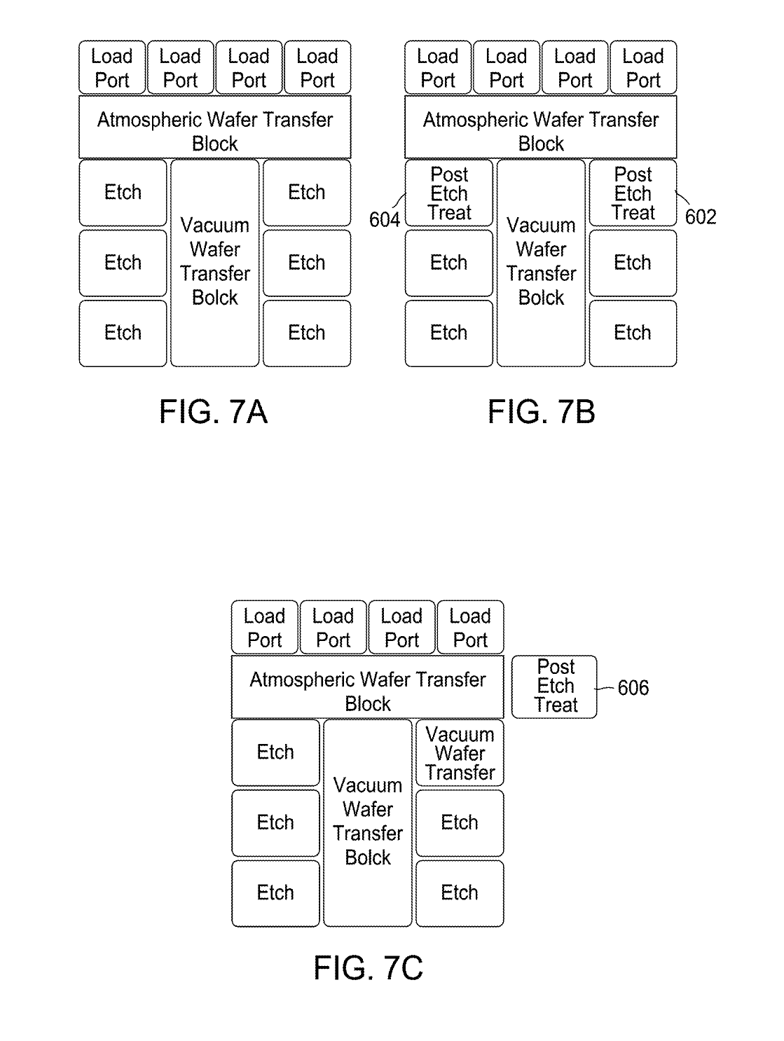

FIGS. 7A, 7B and 7C show example embodiments of substrate processing tools. The system of FIG. 7A shows a conventional configuration that has six etch chambers. The system of FIG. 7B illustrates an embodiment in which two etch chambers of FIG. 7A have been replaced with post-etch treatment chambers 602, 604. The system of FIG. 7C is an alternative platform configuration with post-etch treatment chamber 606 on atmospheric transfer block (vacuum or atmospheric process chamber).

In other embodiments, the fluorinated polymer residue can be modified to become hydrophobic or hydrophilic by irradiating the substrate with UV prior to depositing the absorption-enhancing material. Additionally, steps of depositing the absorption-enhancing material on the substrate, irradiating the absorption-enhancing material, and executing the wet clean process can all be executed within a single processing chamber or within a various modules of a single processing tool or platform.

Other embodiments can include heating the substrate while irradiating the fluorinated polymer residue and the absorption-enhancing material. Heating can be accomplished using any of the mechanism described above, such as be a heated chuck, infrared light, or a broadband flash lamp. A given substrate can be heated between 25 degrees Celsius and 400 degrees Celsius. A given duration for this polymer modification treatment can depend on type of underlying layer, thickness of polymer, light intensity, polymer thickness, type of dye, etc. In another embodiment, the substrate is heated to a predetermined temperature based on material properties of the one or more underlying layers. For example, if a given film under the polymer residue is thermally cured (not UV cured) and susceptible to high heat, then visible light can be used and a temperature sufficiently low to prevent damage to the underlying layer. If it is determined that the underlying layer is not impervious to UV and/or higher temperatures, then the substrate can be maintained at relatively higher temperatures and flood exposed with higher intensity light for a relatively shorter exposure duration, which can increase throughput.

Accordingly, techniques herein enable the ability to selectively improve the radiation absorption of films on a substrate and consequently generate singlet oxygen by intersystem crossing. Higher concentrations of singlet oxygen accelerate further incorporation of oxygen species into the polymer film and aid in removal of CF₂ bonds in the post etch polymer to enable a successful post etch clean.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method for processing a substrate, the method comprising:
receiving a substrate having fluorinated polymer residue on a surface of the substrate;
treating the fluorinated polymer residue to provide a treated fluorinated polymer residue having increased sensitivity to electromagnetic (EM) radiation exposure; and
exposing the treated fluorinated polymer residue to EM radiation in an oxygen-containing environment to facilitate a cleaning process for removing the fluorinated polymer residue from the substrate.

2. The method of claim 1 wherein said treating comprises depositing an absorption-enhancing material on the substrate, the absorption-enhancing material having a light-absorption capacity greater than a light-absorption capacity of the fluorinated polymer residue.

3. The method of claim 2, wherein said depositing comprises depositing a chromophore on the substrate, the chromophore having a UV light-absorption capacity greater than a UV light-absorption capacity of the fluorinated polymer residue.

4. The method of claim 2, wherein the absorption-enhancing material includes a species selected from the group consisting of monomer species, oligomer species, and polymer species, the species containing carbonyl groups that increase absorption of electromagnetic radiation that causes generation of singlet oxygen.

5. The method of claim 2, wherein the absorption-enhancing material is deposited via vapor phase deposition, via initiated chemical vapor deposition (iCVD) or via spin-on deposition of a liquid comprising a solvent and solute.

6. The method of claim 5, wherein the absorption-enhancing material is deposited via said vapor phase deposition which comprises exposing the substrate to peroxygen species.

7. The method of claim 5, wherein the absorption-enhancing material is deposited via spin-on deposition and the liquid includes a species selected from the group consisting of monomer, oligomer, and polymer.

8. The method of claim 3, further comprising depositing fluorine-scavenging species with the chromophore.

9. The method of claim 2, wherein the absorption-enhancing material comprises one or more dyes, the method further comprising matching one or more light sources to the one or more dyes such that the one or more light sources respectively provide light wavelengths at peak absorption values of the one or more dyes for generating singlet oxygen.

10. The method of claim 2, further comprising:
selecting a broadband light source for irradiating the fluorinated polymer residue and the absorption-enhancing material in an oxygen-containing environment; and
selecting two or more dyes for the absorption-enhancing material, the two or more dyes having a light absorption spectrum that matches the broadband light source.

11. The method of claim 2, wherein depositing the absorption-enhancing material on the substrate increases a sensitivity of the fluorinated polymer residue to light with respect to breaking chemical bonds within the fluorinated polymer residue.

12. The method of claim 2, wherein said exposing comprises irradiating the substrate with ultraviolet light and visible spectrum light.

13. The method of claim 12, wherein the ultraviolet light includes wavelengths that generate singlet oxygen from the absorption-enhancing material.

14. The method of claim 13, wherein the visible spectrum light includes wavelengths that generate singlet oxygen from the absorption-enhancing material.

15. The method of claim 2, wherein said steps of depositing the absorption-enhancing material on the substrate, irradiating the absorption-enhancing material, and executing the wet clean process are all executed within a single processing chamber.

16. The method of claim 2, further comprising, modifying the fluorinated polymer residue to become hydrophobic by irradiating the substrate with UV in an oxygen containing atmosphere prior to depositing the absorption-enhancing material.

17. The method of claim 2, further comprising heating the substrate while irradiating the fluorinated polymer residue and the absorption-enhancing material.

18. The method of claim 17, wherein:
said heating the substrate includes heating the substrate between 25 degrees Celsius and 400 degrees Celsius; and
said irradiating includes irradiating the substrate with visible spectrum light.

19. The method of claim 2, further comprising performing a plasma-based etch transfer of a given relief pattern into one or more underlying layers of the substrate, a plasma of the plasma-based etch transfer including fluorine-containing and hydrocarbon-containing gasses, wherein said fluorinated polymer residue is deposited as a result of said performing a plasma-based etch transfer.

20. The method of claim 1, further comprising after said exposing, executing a wet clean process that uses liquid chemistry to remove the fluorinated polymer residue from the substrate.
